(19) United States
(12) Patent Application Publication
(10) Pub. No.: US 2024/0264038 A1
(43) Pub. Date: Aug. 8, 2024

(54) PROBE CARD

(71) Applicant: SK hynix Inc., Icheon-si (KR)

(72) Inventors: Sung Wook CHO, Icheon-si (KR); Yeon Su YEO, Icheon-si (KR)

(21) Appl. No.: 18/357,018

(22) Filed: Jul. 21, 2023

(30) Foreign Application Priority Data
Feb. 7, 2023 (KR) 10-2023-0016269

(51) Int. Cl. G01M 11/02; G01R 1/073; G01R 31/28

(52) U.S. Cl. CPC G01M 11/0214; G01R 1/07314; G01R 31/2886

(57) ABSTRACT

Probe cards that can replace lens units are disclosed. In some implementations, a probe card may include a lens unit through which light irradiated from a light source unit; a jig into which the lens unit is inserted inside, and a holder unit for closely supporting the lens unit.

### PRIORITY CLAIM AND CROSS REFERENCE TO RELATED APPLICATION

This patent document claims the priority and benefits of Korean Patent Application No. 10-2023-0016269, filed on Feb. 7, 2023, which is incorporated by reference in its entirety as part of the disclosure of this patent document.

### TECHNICAL FIELD

Various embodiments of the disclosed technology relate to a probe card.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smart phones, digital cameras, game machines, IoT (Internet of Things), robots, security cameras and medical micro cameras.

The image sensing device may be roughly divided into charge coupled device (CCD) image sensing devices and complementary metal oxide semiconductor (CMOS) image sensing devices.

Image sensing devices have unique testing requirements to ensure their optimal operation, and probe cards can be used to test the functioning of the image sensing devices when they are still on a wafer. Some of the probe cards used in such a wafer test include lenses to evaluate optical characteristics of the image sensing devices, and the relationship between a wafer test result using the lenses and an evaluation result of modules that include image sensing devices separated from the wafer can be used to predict the characteristics of the modules.

### SUMMARY

The disclosed technology can be implemented in some embodiments to provide a probe card capable of replacing lenses without an additional processing.

In an embodiment, a probe card may include: a lens unit through which light irradiated from a light source unit; a jig into which the lens unit is inserted inside, and a holder unit for closely supporting the lens unit.

The holder unit may include a protrusion part supported by an inner surface of the jig.

The holder unit may include a first through hole into which the lens unit is inserted.

The lens unit may be inserted into the holder unit through the first through hole and supported by an inner surface of the holder.

The lens unit may be supported by an upper end of the holder unit.

The holder unit may include a rubber material.

The jig may include a plurality of second through holes into which the lens unit is inserted.

The jig may include an inclined part structured to support the protrusion part of the holder unit.

The holder unit may be structured to be separated from the jig or inserted into the jig.

In an embodiment, a probe card may include: a jig includes a plurality of through holes, a lens unit inserted into the jig through one of the plurality of through holes, and a holder unit for holding the lens unit.

The holder unit may be supported by an inner lower portion of the jig.

The holder unit may include a protrusion part formed on a side of the holder unit to be supported by the inner lower portion of the jig.

The jig may taper toward the inner lower portion of the jig such that the protrusion part is supported by the inner lower portion of the jig.

The jig may taper toward a bottom of the jig such that an outer diameter of the jig at a top of the jig is greater than an outer diameter of the jig at a bottom of the jig .

The lens unit may be supported by an upper circumferential surface of the holder unit.

The holder unit may include a plastic material.

In an embodiment, a probe card for testing an imaging sensor may include a lens unit configured to focus light that is generated by a light source unit and passes through the lens unit, a holder unit structured to support the lens unit disposed in the holder unit, and a jig structured to accommodate the holder unit and the lens unit disposed in the holder unit, wherein the holder unit supports the lens unit inserted into the jig. In some implementations, the holder unit has a coefficient of friction that is higher than a coefficient of friction of a portion of the jig near the holder unit.

In an embodiment, a probe card may include a jig includes a plurality of through holes, a lens unit inserted into the jig through one of the plurality of through holes, and a holder unit disposed in the jig and structured to hold the lens unit. In some implementations, the holder unit has a coefficient of friction that is higher than a coefficient of friction of a portion of the jig near the holder unit.

Lens replacement is possible without the need to process the existing probe card or replace it with a new probe card for lens replacement.

Since only the lens can be attached and detached without the need to replace the probe card, it is possible to save time and cost due to manufacturing a new probe card and resources required for manufacturing a new probe card.

In addition, since the lens is detachable, maintenance and lens change are easy.

### BRIEF DESCRIPTION OF THE DRAWINGS

FIG. 1 is a cross-sectional view of an example of a probe card based on an embodiment of the disclosed technology.

FIG. 2 is a plan view of an example of a holder unit based on an embodiment of the disclosed technology.

FIG. 3 is a cross-sectional view of an example of a probe card based on an embodiment of the disclosed technology.

FIG. 4 is a cross-sectional view of an example of a probe card based on an embodiment of the disclosed technology.

### DETAILED DESCRIPTION

Features, and certain advantages in connection with specific implementations of the disclosed technology disclosed in this patent document are described by embodiments and examples with reference to the accompanying drawings.

Probe cards that include lenses can be used in a wafer test to evaluate optical characteristics of image sensing devices on a wafer. Depending on the type of lens in the probe cards, a chief ray angle (CRA) varies widely, and thus correlation values between evaluation result data (e.g., the relationship between a wafer test result using the lenses and an evaluation result of modules that include image sensing devices separated from the wafer) that is obtained through the wafer test using the probe cards can vary, thereby generating discrepancies in the correlation values. In order to address such issues, a lens mounted on a probe card can be replaced with another lens similar to the target product. For example, if the CRA of the replaced lens differs from the CRA of the lens used previously, the lens mounted on the probe card is replaced.

In some cases, once a lens is attached to a probe card, it is difficult to separate the lens from the probe card without using physical force or a new probe card may be needed, increasing the cost of the wafer test.

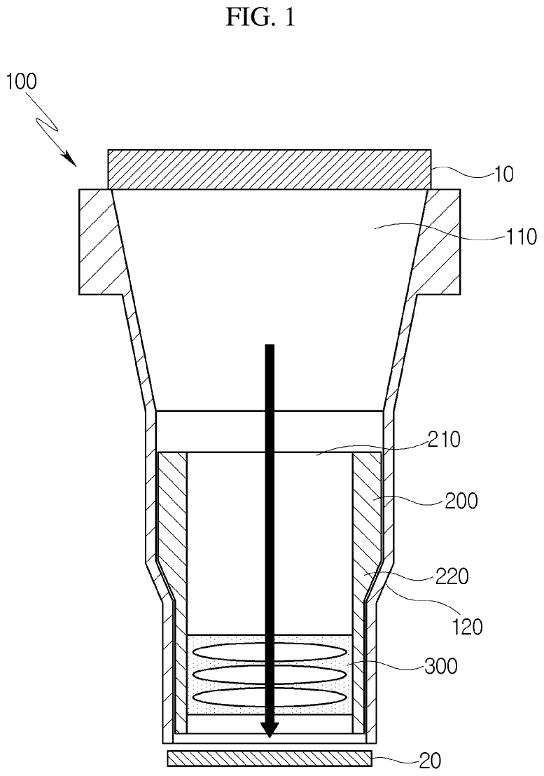

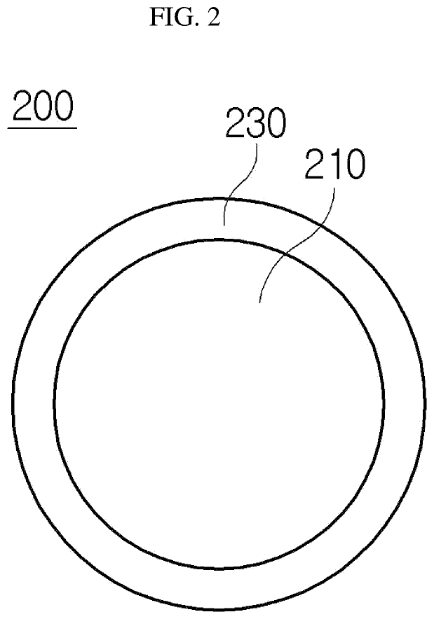

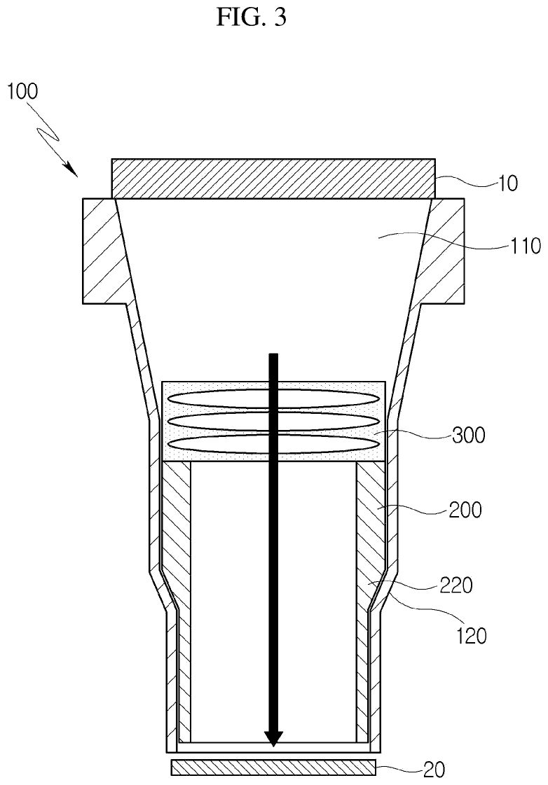

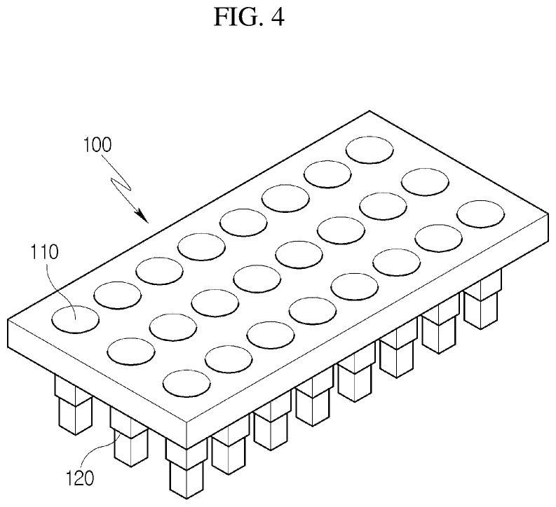

FIG. 1 is a cross-sectional view of an example of a probe card based on an embodiment. FIG. 2 is a plan view of an example of a holder unit based on an embodiment. FIG. 3 is a cross-sectional view of an example of a probe card based on an embodiment. FIG. 4 is a cross-sectional view of an example of a probe card based on an embodiment.

In some implementations, during a wafer test of the wafer 20, a probe card is disposed between a light source unit 10 and a wafer 20.

The light source unit 10 is located at a top of a jig 100 and light beams generated by a light source can be incident on the wafer 20 with through a second through hole 110 of the jig 100. The light beams generated by the light source may pass through the lens unit 300 and may be incident on the wafer 20.

In some implementations, the wafer 20 may including a plurality of CMOS image sensor (CIS) devices. In some implementations, the wafer 20 may include a plurality of semiconductor devices such as other types of sensor devices, memory devices, and processors. Although not depicted in drawings, examples of the CIS devices may include an active pixel sensor that includes a photo diode configured to convert incident light corresponding to an optical image into electrical signals, and a peripheral circuit configured to control the operations of the photo diode. In some implementations, an image sensor may include a pixel array that includes a plurality of two-dimensionally arranged pixels to convert the optical image into the electrical signals. The peripheral circuit may include, for example, a timing generator, a row/column scanner, a correlated double sampler, a gain amplifier, and an analogue-to-digital converter (ADC) converter.

In order to evaluate the performance of an image sensing device, various test items such as sensitivity, a noise, and an operational range are measured, and optical features of the image sensing device can be measured using an optical input source that generates light. For example, the light source unit 10 may illuminate light to the wafer 10 to measure optical features of image sensing devices on the wafer 10.

Referring to FIG. 1, in some embodiments of the disclosed technology, the probe card includes a jig 100, a holder unit 200, and a lens unit 300.

The jig 100 may be disposed between the light source unit 10 and the wafer 20 and may have a second through hole 110 into which the holder unit 200 and the lens unit 300 are inserted.

The holder unit 200 and the lens unit 300 may be inserted into the jig 100 through the second through hole 110.

An upper diameter of the second through hole 110 may be larger than a lower diameter of the second through hole 110. In some implementations, the second through hole 110 tapers toward the bottom of the second through hole 110. In some implementations, a radius of the second through hole 110 at a top of the second through hole 110 is greater than the radius of the second through hole 110 near a top of the holder unit 200.

As an example, the jig 100 may be formed such that its outer diameter decreases from a top to a bottom thereof.

In some implementations. the jig 100 may include an inclined part 120 supporting a protrusion part 220 of the holder unit 200.

As an example, the holder unit 200 may have a first through hole 210 into which the lens unit 300 is inserted.

As an example, the holder unit 200 may include a rubber or plastic material.

The holder unit 200 may support the lens unit 300 through a frictional force between the holder unit 200 and an outer surface of the lens unit 300.

Since a position of the lens unit 300 may be adjusted and held in the adjusted position because of a frictional force within the holder unit 200, a flange back length (FBL) may be freely adjusted. In some implementations, the holder unit 200 may have a coefficient of friction higher than coefficients of friction of other portions of the second through hole 110 near the holder unit 200.

As an example, the holder unit 200 may have the protrusion part 220 that is fixed and supported by the inclined part 120 inside the jig 100.

A lower end of the protrusion part 220 may be formed to taper downward in a direction toward the wafer 20.

The holder unit 200 is easily detachable and may be separated from the jig 100 or attached to an inside of the jig 100 through the protrusion part 220.

In some implementations, the lens unit 300 inside the jig 100 may be fixed using the holder unit 200 or the lens unit 300 may be separated from the holder unit 200 and may be extracted to the outside of the jig 100. Since the user may attach and detach only the lens unit 300 through the holder unit 200 without replacing the probe card, it is possible to reduce time and cost that would have been required to replace the lens.

As an example, the lens unit 300 passes light irradiated from the light source unit 10 and may include a single lens or a plurality of lenses.

As an example, the lens unit 300 may be a module type component including a single lens or a plurality of lenses.

Although not illustrated in the drawings, the lens unit 300 may be a single lens as an example. It is possible to separate the lens included in the module type component and fix it to the holder unit 200.

As an example, the lens unit 300 may be inserted into the holder unit 200 through the first through hole 210 of the holder unit 20 and may be supported by the holder unit 200.

A thickness between an upper inner surface and an upper outer surface of the holder unit 200 may be greater than a thickness between an inner lower surface and a lower outer surface.

Through the holder unit 200, various types of lenses may be freely inserted into or extracted from and attached to or detached from a probe card having no lens therein.

Referring to FIGS. 2 and 3, as an example, the lens unit 300 may be supported by a top surface 230 of the holder unit 200.

As an example, the lens unit 300 having a large size that cannot be inserted into the first through hole 210 may be supported by the top surface 230 of the holder unit 200.

As an example, the lens unit 300 may be supported by an upper circumferential surface 230 of the holder unit 200.

A lens having a larger diameter than a diameter of the first through hole 210 of the holder unit 200 may be disposed on the top surface 230 of the holder unit 200.

In the case of a lens included in a module-type component that is difficult to insert into the holder unit 200, the lens may be disposed on the top surface 230 of the holder unit 200.

Referring to FIG. 4, as an example, a plurality of second through holes 110 may be formed in the jig 100.

As an example, the lens unit 300 may be inserted into the jig 100 through any one of the plurality of second through holes 110.

The inclined part 120 may be formed below the plurality of second through holes 110 of the jig 100 so as to be inclined downward.

As an example, a plurality of holder units 200 may be inserted into and supported by an inner lower portion of the plurality of second through holes 110 of the jig 100.

The protrusion part 220 may be formed on a side of the holder unit 200 to be supported by the inner lower portion of the plurality of second through holes 110 of the jig 100.

In some embodiments of the disclosed technology, since the lens unit 300 may be placed inside the holder unit 200 or on a top of the holder unit 200 through the holder unit 200, lens replacement is possible without the need to process the existing probe card or replace the probe card. In addition, in some embodiments of the disclosed technology, since only the lens may be attached or detached without the need to replace the probe card, it is possible to reduce time and cost that would have been required to manufacture a new probe card. In addition, since the lens may be detached based on some embodiments of the disclosed technology, maintenance of the probe card becomes easy.

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples are described and other implementations, enhancements and variations can be made based on what is described and illustrated in this patent document.

What is claimed is:

1. A probe card, comprising:
a lens unit through which light irradiated from a light source unit;
a jig into which the lens unit is inserted inside, and
a holder unit for closely supporting the lens unit.

2. The probe card of claim 1, wherein the holder unit includes a protrusion part supported by an inner surface of the jig.

3. The probe card of claim 1, wherein the holder unit includes a first through hole into which the lens unit is inserted.

4. The probe card of claim 3, wherein the lens unit is inserted into the holder unit through the first through hole and supported by an inner surface of the holder.

5. The probe card of claim 1, wherein the lens unit is supported by an upper end of the holder unit.

6. The probe card of claim 1, wherein the holder unit includes a rubber material.

7. The probe card of claim 1, wherein the jig includes a plurality of second through holes into which the lens unit is inserted.

8. The probe card of claim 2, wherein the jig includes an inclined part structured to support the protrusion part of the holder unit.

9. The probe card of claim 1, wherein the holder unit is structured to be separated from the jig or inserted into the jig.

10. A probe card, comprising:
a jig includes a plurality of through holes,
a lens unit inserted into the jig through one of the plurality of through holes, and
a holder unit for holding the lens unit.

11. The probe card of claim 10, wherein the holder unit is supported by an inner lower portion of the jig.

12. The probe card of claim 11, wherein the holder unit includes a protrusion part formed on a side of the holder unit to be supported by the inner lower portion of the jig.

13. The probe card of claim 12,
wherein the jig tapers toward the inner lower portion of the jig such that the protrusion part is supported by the inner lower portion of the jig.

14. The probe card of claim 12,
wherein the jig tapers toward a bottom of the jig such that an outer diameter of the jig at a top of the jig is greater than an outer diameter of the jig at a bottom of the jig.

15. The probe card of claim 10,
wherein the lens unit is supported by an upper circumferential surface of the holder unit.

16. The probe card of claim 10,
wherein the holder unit includes a plastic material.
